(19) United States
(12) Patent Application Publication
(10) Pub. No.: US 2015/0155435 A1
(43) Pub. Date: Jun. 4, 2015

(54) LIGHT EMITTING DEVICE AND ILLUMINATION SYSTEM HAVING THE SAME

(71) Applicant: Samsung Electronics Co., Ltd., Suwon-si (KR)

(72) Inventor: Masami Nei, Suwon-si (KR)

(21) Appl. No.: 14/320,860

(22) Filed: Jul. 1, 2014

(30) Foreign Application Priority Data
Dec. 3, 2013 (KR) 10-2013-0149099

(51) Int. Cl. H01L 33/20; H01L 33/62; H01L 27/15; H01L 33/36

(52) U.S. Cl. CPC H01L 33/20; H01L 33/36; H01L 33/62; H01L 27/156

(57) ABSTRACT

A light emitting device may include a substrate having a circuit pattern and at least one light emitting diode (LED) chip. The LED chip may include electrode pads provided on one surface thereof disposed on the circuit pattern to be electrically connected to the circuit pattern. The electrode pads may be rotationally symmetrical with respect to the center of the surface of the LED chip and the circuit pattern may have at least one wiring cell defining a mounting area in which the LED chip is mounted. The shape of the wiring cell may correspond to that of the LED chip.

### CROSS-REFERENCE TO RELATED APPLICATION

This application claims the benefit of Korean Patent Application No. 10-2013-0149099 filed on Dec. 3, 2013, with the Korean Intellectual Property Office, the disclosure of which is incorporated herein by reference.

### BACKGROUND

The present disclosure relates to a light emitting device and an illumination system having the same.

Among light emitting devices, a chip on board (COB) module may be formed by stacking an insulating layer on an aluminum substrate, forming a predetermined circuit pattern thereon to prepare a metal core printed circuit board (MCPCB), and directly mounting a light emitting diode (LED) chip on the MCPCB using a flip chip bonding method, for example.

Because electrode pads of LED chips are asymmetrical, positions, directions, and other layout factors for conventional COB modules may be limited, which may result in poorer lighting performance. For example, in a high-power lighting module that employs a plurality of LED chips, the LED chips should be arranged in a dense arrangement in order to provide uniform light distribution. However, the asymmetrical configuration of conventional LED chips impedes the design of such a layout.

### SUMMARY

In exemplary embodiments in accordance with principles of inventive concepts, a light emitting device includes a substrate having a circuit pattern; and at least one light emitting diode (LED) chip including electrode pads provided on one surface thereof disposed on the circuit pattern to be electrically connected to the circuit pattern, wherein the electrode pads are rotationally symmetrical with respect to the center of the surface of the LED chip, and the circuit pattern has at least one wiring cell defining a mounting area in which the LED chip is mounted.

In exemplary embodiments in accordance with principles of inventive concepts, electrode pads include a first pad disposed at the center of the surface of the LED chip; and a plurality of second pads disposed at the perimeter of the surface of the LED chip while having rotational symmetry with respect to the first pad.

In exemplary embodiments in accordance with principles of inventive concepts, the shape of the first pad and of the wiring cell correspond to that of the surface of the LED chip.

In exemplary embodiments in accordance with principles of inventive concepts, the plurality of second pads is spaced apart from one another at regular intervals to be disposed in a non-continuous ring arrangement surrounding the first pad.

In exemplary embodiments in accordance with principles of inventive concepts, the plurality of second pads is disposed at corners of the perimeter of the surface of the LED chip.

In exemplary embodiments in accordance with principles of inventive concepts, the circuit pattern includes: a first pattern disposed at the center of the wiring cell; and a second pattern disposed at the perimeter of the wiring cell and surrounding the first pattern while being formed as an open curve having an opening.

In exemplary embodiments in accordance with principles of inventive concepts, the first pattern includes a first extension pattern extended to the outside of the second pattern through the opening, and the second pattern includes a second extension pattern extended from one side thereof.

In exemplary embodiments in accordance with principles of inventive concepts, the shape of the first pattern corresponds to that of the first pad disposed on a top surface of the first pattern, and the first extension pattern is disposed between the plurality of second pads.

In exemplary embodiments in accordance with principles of inventive concepts, the second pattern is disposed at a position corresponding to the plurality of second pads disposed on a top surface of the second pattern, and the second pattern is formed as an open curve corresponding to the non-continuous ring arrangement of the plurality of second pads.

In exemplary embodiments in accordance with principles of inventive concepts, the at least one LED chip has a triangular shape, a quadrangular shape, or a hexagonal shape.

In exemplary embodiments in accordance with principles of inventive concepts, the at least one wiring cell comprises a plurality of wiring cells disposed on the substrate and connected to one another in series and in parallel, and the substrate comprises electrode terminals supplying external power to the wiring cells.

In exemplary embodiments in accordance with principles of inventive concepts, a light emitting device includes a sealing part covering the at least one LED chip and the circuit pattern.

In exemplary embodiments in accordance with principles of inventive concepts, an illumination system includes a base having an electrical connection structure; and at least one light emitting device mounted on the base and electrically connected to the electrical connection structure, wherein the at least one light emitting device is a light emitting device including a substrate having a circuit pattern; and at least one light emitting diode (LED) chip including electrode pads provided on one surface thereof disposed on the circuit pattern to be electrically connected to the circuit pattern, wherein the electrode pads are rotationally symmetrical with respect to the center of the surface of the LED chip, and the circuit pattern has at least one wiring cell defining amounting area in which the LED chip is mounted.

In accordance with principles of inventive concepts, a illumination system includes a cover unit mounted on the base.

In accordance with principles of inventive concepts an illumination system includes a reflector mounted on the base.

In accordance with principles of inventive concepts an apparatus includes an LED chip including an LED having anode and cathode electrodes; and electrode pads, the pads including a first pad for connection to either the anode or cathode and a plurality of second pads arranged in a broken ring around the first pad, the second pads connected to the LED electrode not connected to the first pad.

In accordance with principles of inventive concepts an LED chip is of a polygonal shape and the second pads are formed at the corners of the polygon.

In accordance with principles of inventive concepts an apparatus includes a substrate having a circuit pattern including a plurality of wiring cells, a wiring cell including a first pattern disposed at the center and in contact with the first pad and a second pattern in contact with the second pads and partially surrounding the first pattern.

In accordance with principles of inventive concepts wiring cells and LED chips have a hexagonal shape.

In accordance with principles of inventive concepts an illumination system includes an LED chip including an LED having anode and cathode electrodes; and electrode pads, the pads including a first pad for connection to either the anode or cathode and a plurality of second pads arranged in a broken ring around the first pad, the second pads connected to the LED electrode not connected to the first pad.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view schematically illustrating a light emitting device in accordance with principles of inventive concepts;

FIG. 2 is a plan view of FIG. 1;

FIG. 3 is a cross-sectional view schematically illustrating a light emitting diode (LED) chip provided in the light emitting device of FIG. 1;

FIGS. 4A and 4B are a bottom view and a side view schematically illustrating the LED chip of FIG. 3, respectively;

FIGS. 5A and 5B are bottom views schematically illustrating modified examples of FIG. 4;

FIG. 6 is a plan view schematically illustrating a circuit pattern provided in the light emitting device of FIG. 1;

FIG. 7 is a view schematically illustrating modified examples of wiring cells in the circuit pattern of FIG. 6;

FIG. 8 is a plan view schematically illustrating a circuit pattern formed of wiring cells arranged on a substrate;

FIG. 9 is a plan view schematically illustrating an electrical connection structure of the wiring cells of FIG. 8;

FIG. 10 illustrates an equivalent circuit of the wiring cells of FIG. 9;

FIG. 11 is an exploded perspective view schematically illustrating an illumination system in accordance with principles of inventive concepts; and

FIGS. 12A and 12B are a perspective view and a cross-sectional view schematically illustrating an illumination system in accordance with principles of inventive concepts, respectively.

### DETAILED DESCRIPTION

Various exemplary embodiments will be described more fully hereinafter with reference to the accompanying drawings, in which exemplary embodiments are shown. Exemplary embodiments may, however, be embodied in many different forms and should not be construed as limited to exemplary embodiments set forth herein. Rather, these exemplary embodiments are provided so that this disclosure will be thorough, and will convey the scope of exemplary embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items. The term “or” is used in an inclusive sense unless otherwise indicated.

It will be understood that, although the terms first, second, third, for example. may be used herein to describe various elements, components, regions, layers and/or sections, these elements, components, regions, layers and/or sections should not be limited by these terms. These terms are only used to distinguish one element, component, region, layer or section from another region, layer or section. In this manner, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. In this manner, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. In this manner, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. In this manner, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Expressions such as “at least one of,” when preceding a list of elements, modify the entire list of elements and do not modify the individual elements of the list.

Hereinafter, exemplary embodiments in accordance with principles of inventive concepts will be explained in detail with reference to the accompanying drawings.

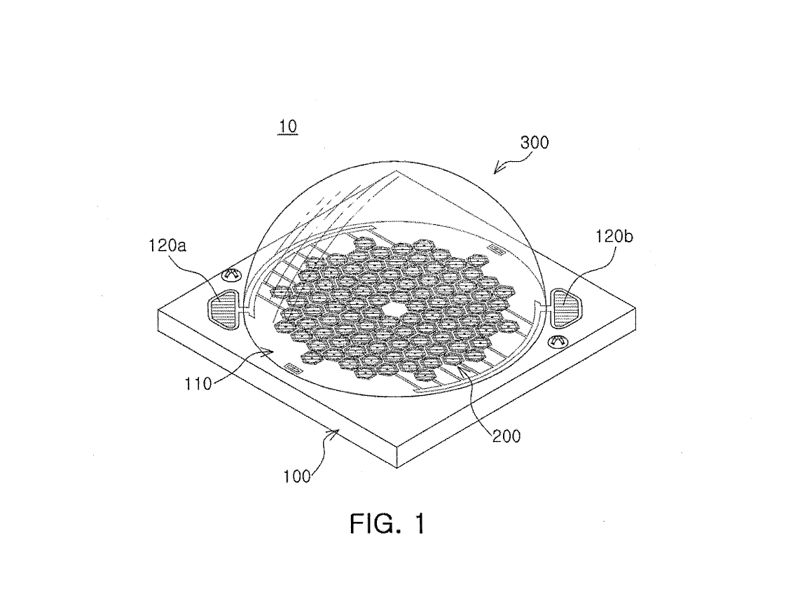

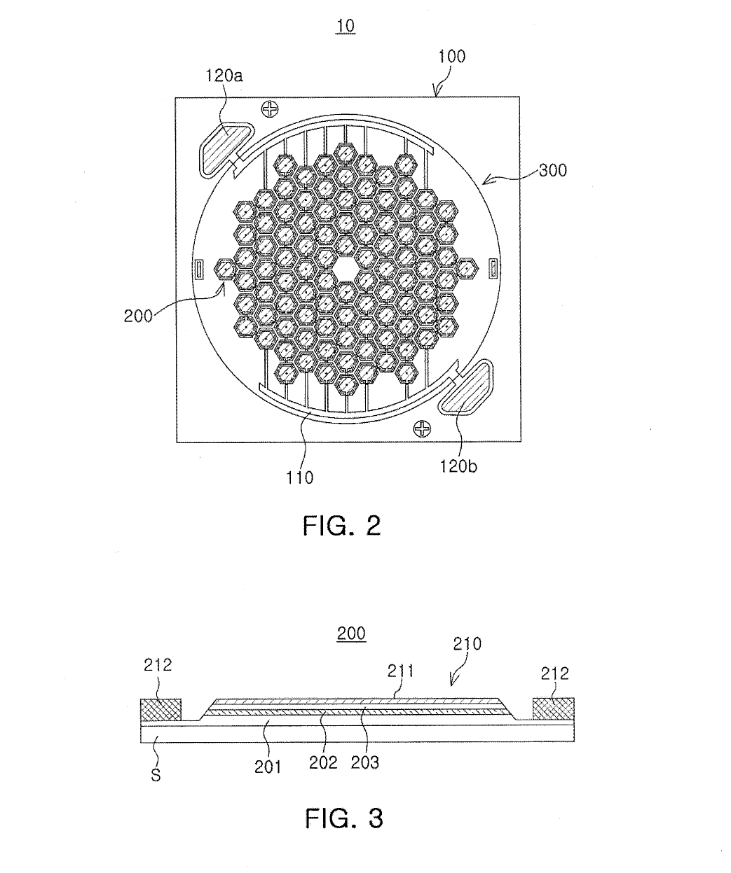

An exemplary embodiment of a light emitting device in accordance with principles of inventive concepts will be described with reference to FIGS. 1 and 2. FIG. 1 is a perspective view schematically illustrating a light emitting device in accordance with principles of inventive concepts, and FIG. 2 is a plan view of FIG. 1.

With reference to FIGS. 1 and 2, a light emitting device 10 in accordance with principles of inventive concepts may include a substrate 100 provided with a circuit pattern 110 and at least one light emitting diode (LED) chip 200 disposed on the circuit pattern 110. The light emitting device 10 may further include a sealing part 300 covering the at least one LED chip 200.

The LED chip 200 is a type of photoelectric device emitting light having a predetermined wavelength when driving power is applied thereto, and may be a semiconductor LED chip in which semiconductor layers are epitaxially grown on a growth substrate S, for example. In exemplary embodiments in accordance with principles of inventive concepts, LED chip 200 may emit blue light, green light, or red light according to materials contained therein, and may also emit white light.

FIG. 3 is a cross-sectional view schematically illustrating an exemplary embodiment of an LED chip 200 applicable to the light emitting device 10 of FIG. 1 in accordance with principles of inventive concepts. LED chip 200 may have a stacked structure of an n-type semiconductor layer 201 and a p-type semiconductor layer 203 with an active layer 202 interposed therebetween on the growth substrate S, for example. In exemplary embodiments in accordance with principles of inventive concepts, n-type and p-type semiconductor layers 201 and 203 may be formed of a material having a composition of AlₓIn_{y}Ga_{(1-x-y)}N, where 0≦x≦1, 0≦y≦1, and 0≦x+y≦1. For example, GaN, AlGaN, InGaN, AlInGaN, or the like may be used.

Active layer 202 disposed between the n-type and p-type semiconductor layers 201 and 203 emits light having a predetermined level of energy through electron-hole recombination. In exemplary embodiments in accordance with principles of inventive concepts, active layer 202 may include a material having an energy band gap smaller than that of the n-type and p-type semiconductor layers 201 and 203. For example, in embodiments in which the n-type and p-type semiconductor layers 201 and 203 include GaN compound semiconductor, the active layer 202 may include InAlGaN compound semiconductor having an energy band gap smaller than that of the GaN compound semiconductor. In addition, the active layer 202 may have a multiple quantum well (MQW) structure in which quantum well layers and quantum barrier layers are alternately stacked. For example, an InGaN/GaN structure may be used therefor in exemplary embodiments in accordance with principles of inventive concepts.

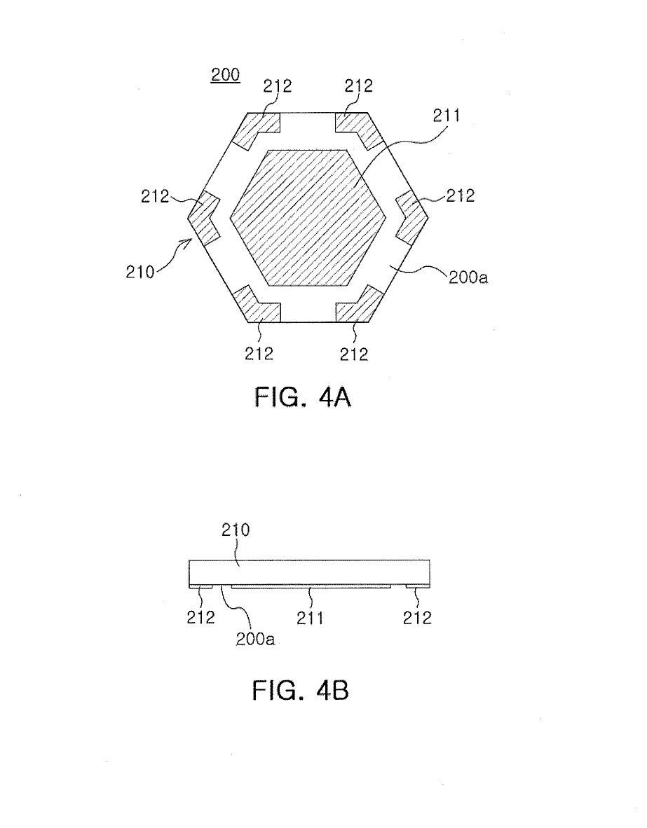

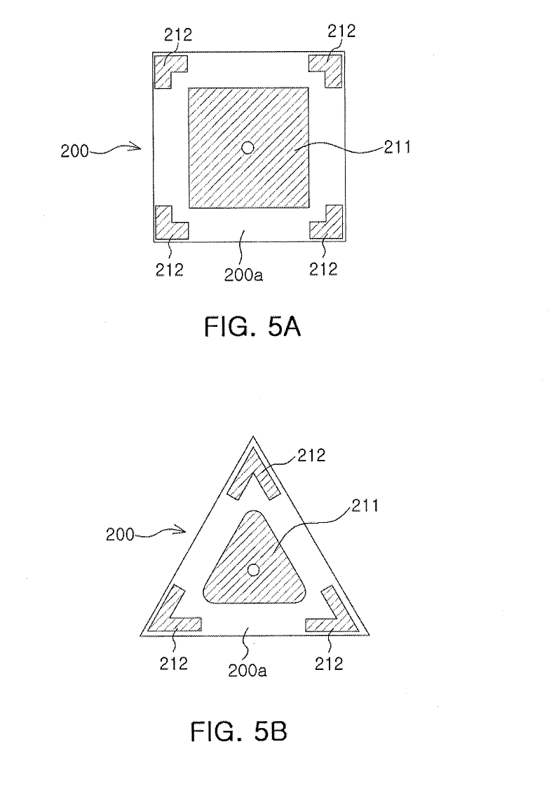

FIGS. 4A and 4B schematically illustrate an exemplary embodiment of LED chip 200 in accordance with principles of inventive concepts. As illustrated in FIG. 4A, the LED chip 200 may have a hexagonal shape, or outline, when viewed from above (that is, a hexagonal shape when viewed in plan-view). However, the shape of exemplary embodiments of the LED chip 200 are not limited thereto. For example, the LED chip 200 may have a quadrangular shape, as illustrated in FIG. 5A, or a triangular shape as illustrated in FIG. 5B, for example and may have any polygonal shape, for example. Although other shapes are contemplated within the scope of inventive concepts, further description herein will focus primarily on embodiments of LED chip 200 having a hexagonal shape.

In exemplary embodiments in accordance with principles of inventive concepts LED chip 200 may include electrode pads 210 (pads 211 and 212 in this exemplary embodiment) electrically connected to the n-type and p-type semiconductor layers 201 and 203. In order to obtain a chip-on-board structure through a flip chip bonding method, the electrode pads 210 may be disposed on a surface 200a of the LED chip 200. In this exemplary embodiment, the surface 200a of the LED chip 200 having the electrode pads formed thereon refers to the surface of the LED chip 200 mounted on the substrate 100.

In exemplary embodiments in accordance with principles of inventive concepts electrode pads 210 may be rotationally symmetrical with respect to the center of the surface 200a and may have axial symmetry with respect to a straight line passing through the center of the surface 200a. As a result, in accordance with principles of inventive concepts, it is not necessary to limit a direction of the LED chip in consideration of the positions of the electrode pads when the LED chip 200 is mounted on the substrate 100 in the manner previously described in relation to conventional LED chips.

As illustrated, the electrode pads 210 may include a first electrode pad 211 disposed at the center of the surface 200a and a plurality of second electrode pads 212 disposed at edges or corners of the surface 200a and surrounding the first pad 211.

In exemplary embodiments in accordance with principles of inventive concepts, the shape of the first pad 211 may correspond to that of the surface 200a. For example, the first pad 211 may have a hexagonal shape as illustrated and edges of the hexagonal first pad 211 disposed at the center of the surface 200a may correspond to those of the hexagonal surface 200a, however embodiments in accordance with principles of inventive concepts are not limited thereto.

The plurality of second pads 212 may be spaced apart from the first pad 211 disposed at the center of the surface 200a at a predetermined interval and may be disposed at the perimeter of the surface 200a while being spaced apart from one another at a predetermined interval, such that they surround the first pad 211. That is, the plurality of second pads 212 may be disposed in the form of a non-continuous ring, not necessarily of a circular overall shape, for example.

In exemplary embodiments in accordance with principles of inventive concepts, the plurality of second pads 212 may be disposed at the corners of the perimeter of the surface 200a. For example, in a case in which the surface 200a of the LED chip 200 has a hexagonal shape, six second pads 212 may be disposed, one each, at the corners of the hexagonal surface 200a. In exemplary embodiments in accordance with principles of inventive concepts, the number of second pads 212 may be changed according to the shape of the LED chip 200.

At least one LED chip 200 may be disposed on the substrate 100 to be fixed and electrically connected thereto. The substrate 100 may include circuit pattern 110 on which the at least one LED chip 200 is disposed, the circuit pattern 110 being electrically connected to the at least one LED chip 200 when the LED chip 200 is disposed on the substrate 100.

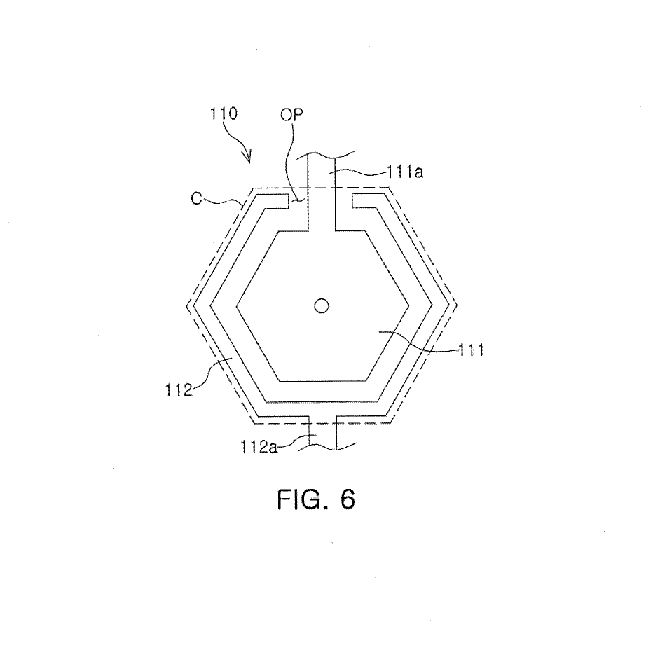

FIG. 6 schematically illustrates an exemplary embodiment of a circuit pattern provided in the light emitting device according to the present embodiment. As illustrated in FIG. 6, the circuit pattern 110 may have a wiring cell C defining a mounting region in which the at least one LED chip 200 is disposed. In exemplary embodiments in accordance with principles of inventive concepts, the shape of the wiring cell C may correspond to that of the LED chip 200.

The circuit pattern 110 may include a first pattern 111 disposed at the center of the wiring cell C and a second pattern 112 spaced apart from the first pattern 111 at a predetermined interval, for example, and surrounding the first pattern 111.

The shape of the first pattern 111 may correspond to that of the first pad 211 disposed on a top surface of the first pattern 111. For example, the first pattern 111 may have a hexagonal shape corresponding to that of the first pad 211.

The second pattern 112 may be disposed at the perimeter of the wiring cell C to correspond to the plurality of second pads 212 disposed on a top surface of the second pattern 112. The second pattern 112 may define an outline of the wiring cell C, for example, and may surround the perimeter of the first pattern 111 while being formed as an open curve having an opening OP corresponding to the non-continuous ring arrangement of the plurality of second pads 212. In exemplary embodiments in accordance with principles of inventive concepts, opening OP may have a size equal to that of an interval between adjacent second pads 212. In a case in which the plurality of second pads 212 is disposed on the second pattern 112, the interval between the adjacent second pads 212 may be placed on the opening OP. In exemplary embodiments in accordance with principles of inventive concepts, the interval between adjacent second pads 212 need not be equal to the size of opening OP, but they are space apart in a manner that ensures that, regardless of the orientation of associated chip, second pads 212 do not contact first pattern 111 but do contact second pattern 112.

First pattern 111 and the second pattern 112 may include a first extension pattern 111a and a second extension pattern 112a, respectively, respectively extended from a side thereof. In particular, the first extension pattern 111a extended from the first pattern 111 may lead to the outside of the second pattern 112 through the opening OP provided in the second pattern 112. In this manner, the first extension pattern 111a may be disposed in the interval between the second pads 212 so that it does not connect to the second pads 212.

The first extension pattern 111a and the second extension pattern 112a may be extended to the outside of the wiring cell C, and may be used to supply driving power to the LED chip 200 disposed on the wiring cell C.

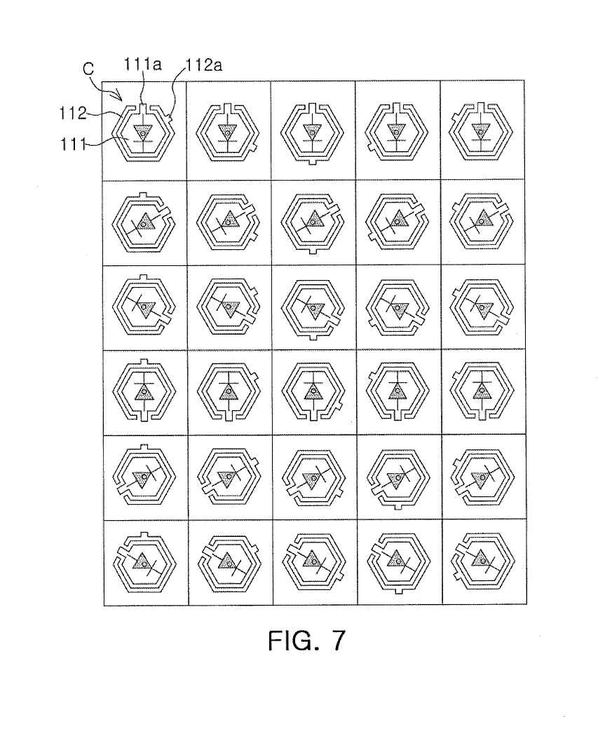

FIG. 7 is a view schematically illustrating various exemplary embodiments of the wiring cells C, each with a different orientation. In an exemplary embodiment such as this, one in which the wiring cells C have a hexagonal shape, thirty different types of wiring cells may be obtained. These modified examples of the wiring cells C may be defined as standard cells. Therefore, in a case in which the circuit pattern 110 is installed on the substrate 100, the thirty different types of wiring cells may be appropriately selected and arranged, in manner that provides the desired light intensity and uniformity (or non-uniformity), in order to satisfy various applications.

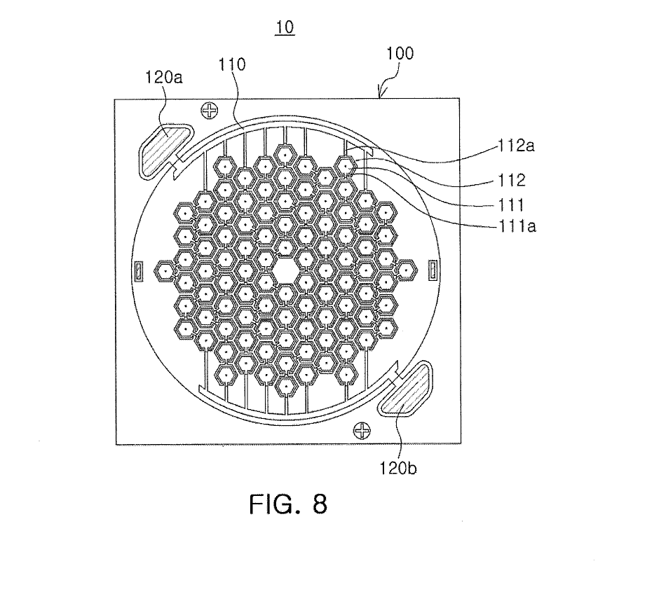

As illustrated in the exemplary embodiment of FIG. 8, the plurality of wiring cells C may be arranged on the substrate 100 to configure the circuit pattern 110. In addition, the plurality of wiring cells C may be appropriately selected from the examples of the wiring cells C illustrated in FIG. 7 according to wiring design.

The plurality of wiring cells C may be arranged at regular intervals within a circular light emitting region, for example. In particular, as the wiring cells C have a hexagonal shape, they may be densely arranged in a honeycomb structure. Therefore, the density of the wiring cells C arranged within a limited light emitting region having a predetermined size may be greater than that associated with a conventional grid pattern.

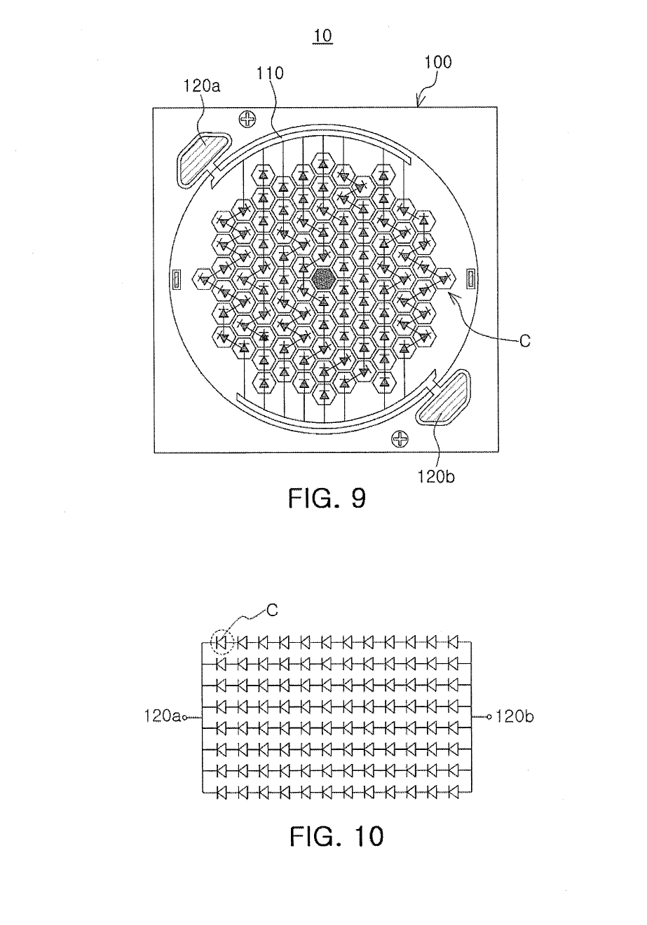

FIG. 9 schematically illustrates a plurality of wiring cells C electrically connected to one another in accordance with principles of inventive concepts and FIG. 10 illustrates a corresponding equivalent circuit of the plurality of connected wiring cells C of FIG. 9.

As illustrated in FIG. 9, the plurality of wiring cells C may be connected to one another in series and in parallel. In order to obtain uniform light distribution, the plurality of wiring cells C may be arranged as the equivalent circuit illustrated in FIG. 10. That is, in exemplary embodiments in accordance with principles of inventive concepts, a plurality of series strings, each string having the same number of wiring cells connected in series, may be connected to one another in parallel.

In the present exemplary embodiment, the circuit pattern has a structure in which eight series strings, each of which has twelve wiring cells C connected in series, are connected to one another in parallel. However, in accordance with principles of inventive concepts, the number of series strings and the number of wiring cells C forming each series string may vary, and are not limited to those illustrated in the present exemplary embodiment.

Since the plurality of wiring cells C is uniformly connected to one another in series and in parallel, uniform light distribution may be achieved throughout the light emitting region in which the plurality of wiring cells C is arranged. In particular, even when the plurality of wiring cells C is densely arranged to form a honeycomb structure within the circular light emitting region, the circuit pattern having uniform series and parallel connections as the equivalent circuit illustrated in FIG. 10 may be readily implemented.

In exemplary embodiments in accordance with principles of inventive concepts, the number of wiring cells C may correspond to the number of LED chips 200 mounted on the substrate 100. However, inventive concepts are not limited thereto and the number of wiring cells C may be greater than that of LED chips 200, for example. In exemplary embodiments in which the number of wiring cells C is greater than that of LED chips 200, the LED chips 200 may be selectively mounted in the wiring cells C to form a circuit pattern of interest.

In exemplary embodiments in accordance with principles of inventive concepts, substrate 100 may be provided with electrode terminals 120a and 120b used to supply external power to the wiring cells C. At least one pair of electrode terminals 120a and 120b having opposite polarities may be provided such that they are connected to the first and second extension patterns 111a and 112a of the wiring cells C.

The sealing part 300 may be disposed on the substrate 100 such that it covers the at least one LED chip 200 and the circuit pattern 110. The sealing part 300 may be formed of a light transmissive material allowing light generated in the LED chip 200 to be emitted externally. For example, silicon resin, epoxy resin, or the like, may be used as the light transmissive material.

The sealing part 300 may be formed by disposing resin on the substrate 100 and curing the resin through heating, light radiation, the passage of time, or the like. In order to adjust a beam spread angle of externally emitted light in accordance with principles of inventive concepts, the sealing part 300 may have a dome shape with a convex top portion, for example. In other exemplary embodiments in accordance with principles of inventive concepts, the top portion of the sealing part 300 may be flat.

In accordance with principles of inventive concepts, sealing part 300 may include at least one wavelength conversion material excited by light generated in the LED chip 200 to convert at least a portion of the light into light having a different wavelength, for example, a phosphor. The wavelength conversion material may be adjusted to emit light of various colors, and a light reflective material may also be contained to spread the emitted light. For example, SiO₂, TiO₂, Al₂O₃, or the like may be used as the light reflective material.

In exemplary embodiments in accordance with principles of inventive concepts, a light emitting device 10 may be formed to have the chip-on-board (COB) type structure through a flip chip bonding method and electrode pads 210 disposed in the same direction may have rotational symmetry and axial symmetry. As a result, it is not necessary to consider the directionality of the LED chip 200 in the case in which the LED chip 200 is mounted on the substrate 100 and, consequently, a circuit pattern may be designed without considering positions, directions and the like of the electrode pads, contrary to designing a circuit pattern according conventional approaches.

In exemplary embodiments in accordance with principles of inventive concepts, LED chips 200 may have a hexagonal shape and may be arranged in a honeycomb structure with high mounting density as illustrated in the drawing. Employing LED chips 200 in accordance with principles of inventive concepts may ease the task of designing the circuit pattern 110 (PCB artwork) to be connected to the electrode pads 210 of the LED chips 200, for example.

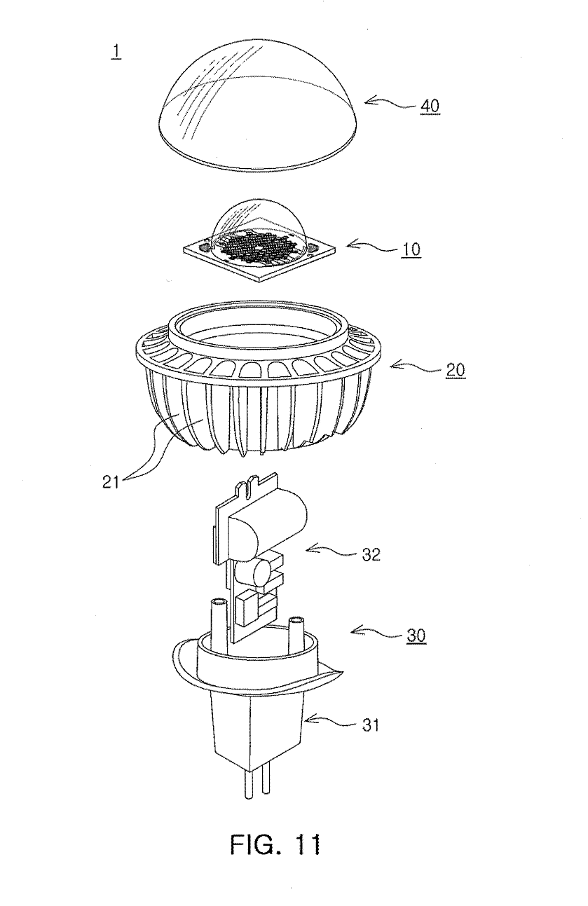

An exemplary embodiment of an illumination system in accordance with principles of inventive concepts will be described with reference to FIG. 11, which is an exploded perspective view schematically illustrating an illumination system in accordance with principles of inventive concepts. Illumination system 1 in accordance with principles of inventive concepts may be a bulb-type lamp, and may be, for example, used as a downlight for indoor lighting. The illumination system 1 may include a base 20 having an electrical connection structure 30 and at least one light emitting device 10 mounted on the base 20. The illumination system 1 may further include a cover unit 40 covering the light emitting device 10.

The light emitting device 10 is a light emitting device in accordance with principles of inventive concepts, such as previously described in the discussion related to FIGS. 1 through 10, and a detailed description thereof will not be repeated here. In an exemplary embodiment, a single light emitting device 10 is mounted on the base 20 by way of example. However, exemplary embodiments are not limited thereto, and a plurality of light emitting devices 10 may be mounted on the base 20, for example.

The base 20 may serve as a frame supporting the light emitting device 10, and may also serve as a heat sink externally dissipating heat generated in the light emitting device 10. To this end, the base 20 may be formed of a material having high heat conductivity and high rigidity. For example, the base 20 may be formed of a metallic material such as aluminum (Al) or a heat dissipating resin.

A plurality of heat radiating fins 21 may be provided to surround an external surface of the base 20 so as to increase the area in contact with air and thereby improve heat dissipation efficiency.

The base 20 may have the electrical connection structure 30 electrically connected to the light emitting device 10. The electrical connection structure 30 may include a terminal unit 31 and a driving unit 32 supplying driving power provided through the terminal unit 31 to the light emitting device 10, for example.

The terminal unit 31 may allow the illumination system 1 to be fastened and electrically connected to a socket, for example. According to exemplary embodiments, the terminal unit 31 may have a pin-type structure inserted into the socket through sliding. Alternatively, the terminal unit 31 may have an Edison-type structure with a screw fastening type thread formed thereon, for example.

The driving unit 32 may supply the driving power to the light emitting device 10 by converting external power into power appropriate for driving the light emitting device 10. For example, the driving unit 32 may be configured of an AC-DC converter, a rectifier circuit part, a fuse, and the like. Driving unit 32 may additionally include a communications module for remote control, a sensor, and other elements, for example.

The cover unit 40 may cover the light emitting device 10 mounted on the base 20, and may have a convex lens shape or a bulb shape. The cover unit 40 may be formed of a light transmissive material, and may include a light diffusion material.

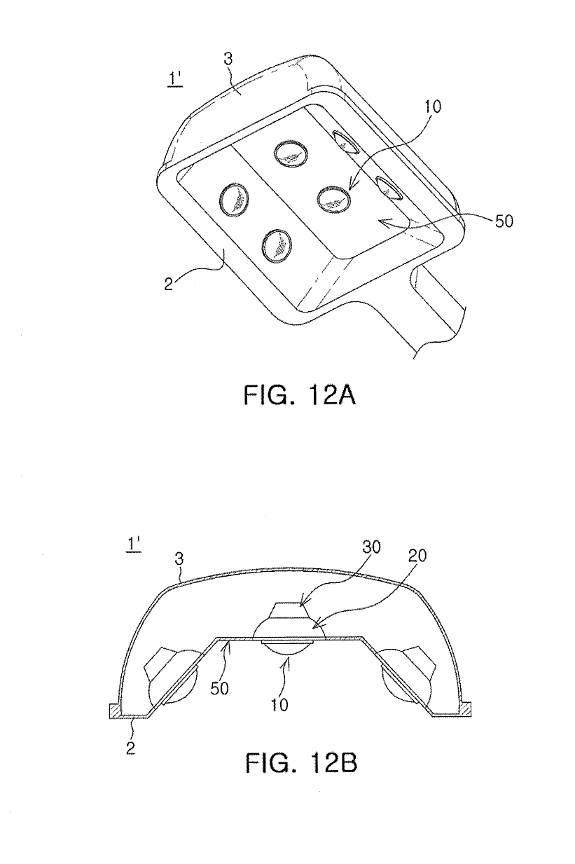

FIG. 12 illustrates an exemplary embodiment of a streetlight as an example of an illumination system 1′ in accordance with principles of inventive concepts. With reference to FIG. 12, the illumination system 1′ according to an exemplary embodiment may include the base 20 having an electrical connection structure, at least one light emitting device 10 mounted on the base 20, and a reflector 50 mounted on the base 20.

The base 20 and the light emitting device 10 configuring the illumination system 1′ may be those described in the discussion related to the exemplary embodiment of FIG. 11, and a detailed description thereof will not be repeated here.

The reflector 50 may be formed of a material having superior light reflectivity. For example, the reflector 50 may include a metallic material. The reflector 50 may be fastened to an internal frame 2 of the streetlight and fixed thereto, and may be covered with an external frame 3 coupled to the internal frame 2 to be protected thereby.

The illumination system using an LED as described above may be classified as an indoor illumination system or an outdoor illumination system, for example. An indoor LED illumination system may include replacements for illumination systems such as a bulb-type lamp, a fluorescent lamp (LED-tube), a flat panel type illumination system replacing an existing lighting fixture (retrofit), and an outdoor LED illumination system may be employed as a streetlight, a security light, a flood light, a scene lamp, or a traffic light, for example.

An illumination system in accordance with principles of inventive concepts using an LED may be utilized as an internal or external light source of a vehicle. As an internal light source of a vehicle, the illumination system using an LED may be used as a dome light, a reading light, or various dashboard light sources. As an external light source of a vehicle, the illumination system using an LED may be used as a headlight, a brake light, a turn signal lamp, a fog light, or a running light, for example.

An LED illumination system in accordance with principles of inventive concepts may be adopted as a light source used in robots or various mechanic facilities. An LED illumination system in accordance with principles of inventive concepts may provide LED lighting using light within a particular wavelength band which may stimulate plant growth, stabilize a user's mood, or treat a disease for example.

An illumination system in accordance with principles of inventive concepts using an LED may be altered in terms of an optical design thereof according to product type, location, and purpose. A technique for controlling lighting by using a wireless (remote) control technique utilizing a portable device such as a smartphone, in addition to a technique of controlling color, temperature and brightness of lighting, may be provided.

In exemplary embodiments in accordance with principles of inventive concepts, a visible light wireless communications technology aimed at achieving a unique purpose of an LED light source and a as a communications unit by adding a communications function to LED illumination systems and display devices may be available. This is because, an LED light source advantageously has a longer lifespan and excellent power efficiency, is capable of implementing various colors, supports a high switching rate for digital communications, and is available for digital control, in comparison to existing light sources.

Visible light wireless communications technology is a wireless communications technology wirelessly transferring information by using light having a visible light wavelength band recognizable by humans' eyes. Visible light wireless communications technology is distinguished from a wired optical communications technology and an infrared wireless communications technology in that it uses light having a visible light wavelength band, and is distinguished from a wired optical communications technology in that its communications environment is based on a wireless scheme.

Unlike RF wireless communications, visible light wireless communications technology has excellent convenience and physical security properties in that it can be used freely without being regulated or needing permission in the aspect of frequency usage, is differentiated in that a user can check a communications link with his/her eyes, and above all, the visible light wireless communications technology is characterized as a convergence technology simultaneously obtaining a unique purpose as a light source and a communications function. LED chips in accordance with principles of inventive concepts may be employed in such visible light communications systems.

As set forth above, in relation to a light emitting device and an illumination system including the same according to exemplary embodiments in accordance with principles of inventive concepts, there is provided a method of designing a circuit pattern with increasing mounting density of LED chips and installing corresponding wiring in various directions with fewer constraints than in conventional illumination systems.

Although exemplary embodiments have been shown and described above, it will be apparent to those skilled in the art that modifications and variations may be made without departing from the spirit and scope of inventive concepts as defined by the appended claims.

What is claimed is:

1. A light emitting device, comprising:
a substrate having a circuit pattern; and
at least one light emitting diode (LED) chip including electrode pads provided on one surface thereof disposed on the circuit pattern to be electrically connected to the circuit pattern,
wherein the electrode pads are rotationally symmetrical with respect to the center of the surface of the LED chip, and
the circuit pattern has at least one wiring cell defining a mounting area in which the LED chip is mounted.

2. The light emitting device of claim 1, wherein the electrode pads include:
a first pad disposed at the center of the surface of the LED chip; and
a plurality of second pads disposed at the perimeter of the surface of the LED chip while having rotational symmetry with respect to the first pad.

3. The light emitting device of claim 2, wherein the shape of the first pad and of the wiring cell correspond to that of the surface of the LED chip.

4. The light emitting device of claim 2, wherein the plurality of second pads is spaced apart from one another at regular intervals to be disposed in a non-continuous ring arrangement surrounding the first pad.

5. The light emitting device of claim 2, wherein the plurality of second pads is disposed at corners of the perimeter of the surface of the LED chip.

6. The light emitting device of claim 2, wherein the circuit pattern includes:
a first pattern disposed at the center of the wiring cell; and
a second pattern disposed at the perimeter of the wiring cell and surrounding the first pattern while being formed as an open curve having an opening.

7. The light emitting device of claim 6, wherein the first pattern includes a first extension pattern extended to the outside of the second pattern through the opening, and
the second pattern includes a second extension pattern extended from one side thereof.

8. The light emitting device of claim 7, wherein the shape of the first pattern corresponds to that of the first pad disposed on a top surface of the first pattern, and
the first extension pattern is disposed between the plurality of second pads.

9. The light emitting device of claim 6, wherein the second pattern is disposed at a position corresponding to the plurality of second pads disposed on a top surface of the second pattern, and
the second pattern is formed as an open curve corresponding to the non-continuous ring arrangement of the plurality of second pads.

10. The light emitting device of claim 1, wherein the at least one LED chip has a triangular shape, a quadrangular shape, or a hexagonal shape.

11. The light emitting device of claim 1, wherein the at least one wiring cell comprises a plurality of wiring cells disposed on the substrate and connected to one another in series and in parallel, and
the substrate comprises electrode terminals supplying external power to the wiring cells.

12. The light emitting device of claim 1, further comprising a sealing part covering the at least one LED chip and the circuit pattern.

13. An illumination system, comprising:
a base having an electrical connection structure; and
at least one light emitting device mounted on the base and electrically connected to the electrical connection structure,
wherein the at least one light emitting device is the light emitting device of claim 1.

14. The illumination system of claim 13, further comprising a cover unit mounted on the base.

15. The illumination system of claim 13, further comprising a reflector mounted on the base.

16. An apparatus, comprising:
an LED chip including an LED having anode and cathode electrodes; and
electrode pads, the pads including a first pad for connection to either the anode or cathode and a plurality of second pads arranged in a broken ring around the first pad, the second pads connected to the LED electrode not connected to the first pad.

17. The apparatus of claim 16, wherein the LED chip is of a polygonal shape and the second pads are formed at the corners of the polygon.

18. The apparatus of claim 17, further comprising a substrate having a circuit pattern including a plurality of wiring cells, a wiring cell including a first pattern disposed at the center and in contact with the first pad and a second pattern in contact with the second pads and partially surrounding the first pattern.

19. The apparatus of claim 18, wherein the wiring cells and LED chips have a hexagonal shape.

20. An illumination system including the apparatus of claim 16.
